(19) United States
(12) Patent Application Publication
(10) Pub. No.: US 2011/0317382 A1
(43) Pub. Date: Dec. 29, 2011

(54) Insulating resin composition and printed circuit substrate using the same

(75) Inventors: Jae Choon Cho, Suwon-si (KR); Hyung Mi Jung, Suwon-si (KR); Choon Keun Lee, Suwon-si (KR)

(73) Assignee: SAMSUNG ELECTRO-MECHANICS CO., LTD., Suwon (KR)

(21) Appl. No.: 12/926,411

(22) Filed: Nov. 16, 2010

(30) Foreign Application Priority Data
Jun. 23, 2010 (KR) 10-2010-0059576

(51) Int. Cl. H05K 1/18; C08L 63/00

(52) U.S. Cl. 361/762; 525/121; 523/400

(57) ABSTRACT

Disclosed herein are an insulating resin composition soluble fluorine-based resin, thermosetting resin; a solvent capable of simultaneously dissolving the soluble fluorine-based resin and the thermosetting resin, and a printed circuit substrate using the same.

### CROSS REFERENCE TO RELATED APPLICATION

This application claims the benefit of Korean Patent Application No. 10-2010-0059576, filed on Jun. 23, 2010, entitled “Insulating Resin Composition And Printed Circuit Substrate Using The Same,” which is hereby incorporated by reference in its entirety into this application.

### BACKGROUND OF THE INVENTION

1. Technical Field

The present invention relates to a printed circuit substrate, and more particularly, to an insulating resin composition including soluble fluorine-based resin and a printed circuit substrate using the same.

2. Description of the Related Art

Recently, a demand for an embedded substrate capable of implementing high integration, compactness, and high performance by embedding multiple or some components in a multi-layer substrate has increased.

Besides the embedded substrate requiring characteristics such as high density, multi-function, and high frequency, insulating materials for forming the embedded substrate also require characteristics, such as low dielectric constant, low loss propertie, etc., together with mechanical properties.

As the insulating materials having characteristics such as low dielectric constant, low loss propertie, etc., a liquid crystal polymer (LCP) or benzocyclobutene (BCB) has been used until now. However, the BCB has a limitation in being applied to the printed circuit substrate due to high price and the LCP has a limitation in being applied to a process of manufacturing the printed circuit substrate due to having thermoplastic resin characteristics.

Therefore, development of insulating materials having characteristics, such as low dielectric constant, low loss propertie, etc., and capable of meeting both the process cost and process performance, is needed.

### SUMMARY OF THE INVENTION

An object of the present invention is to provide an insulating resin composition including soluble fluorine-based resin and a printed circuit substrate using the same.

According to an aspect of the present invention, there is provided an insulating resin composition, including: soluble fluorine-based resin; thermosetting resin; and a solvent capable of simultaneously dissolving the soluble fluorine-based resin and the thermosetting resin.

The fluorine-based resin may include poly vinylidene fluoride or derivatives thereof.

The content of the fluorine-based resin may be in the range of 5 parts by weight to 40 parts by weight for the entire content of the insulating resin composition.

The solvent may be made of any one of an ester-based solvent and an amine-based solvent or a mixture thereof.

The solvent may include methyl ethyl ketone, dimethylacetamide, ethanolamine, isopropanolamine, and triethanolamine or a mixture of two or more thereof.

The thermosetting resin may include any one or two or more of epoxy-based resin, phenol-based resin, acryl-based resin, and imide-based resin.

The insulating composition may further include an inorganic filler.

According to another aspect of the present invention, there is provided a printed circuit substrate using an insulating resin composition, including: an insulator including cavities; electronic components disposed in the cavities; and a buildup layer that includes an insulating layer disposed on at least any one of the top and bottom surfaces of the insulator including a semiconductor device and a circuit layer disposed on the top surface of the insulating layer to form an interlayer connection thereto, wherein at least any one of the insulator and the insulating layer include a solvent capable of dissolving soluble fluorine-based resin, thermosetting resin, and both the soluble fluorine-based resin and the thermosetting resin.

The fluorine-based resin may include poly vinylidene fluoride or derivatives thereof.

The content of the fluorine-based resin may be in the range of 5 parts by weight to 40 parts by weight for the entire content of the insulating resin composition.

The solvent may be made of any one of an ester-based solvent and an amine-based solvent or a mixture thereof.

The solvent may include methyl ethyl ketone, dimethylacetamide, ethanolamine, isopropanolamine, and triethanolamine or a mixture of two or more thereof.

The thermosetting resin may include any one or two or more of epoxy-based resin, phenol-based resin, acryl-based resin, and imide-based resin.

The insulating composition may further include an inorganic filler.

### BRIEF DESCRIPTION OF THE DRAWINGS

FIG. 1 is a cross-sectional view of a printed circuit substrate according to an exemplary embodiment of the present invention.

### DESCRIPTION OF THE PREFERRED EMBODIMENTS

Hereinafter, the exemplary embodiments of the present invention will be described in detail with reference to the drawings of a printed circuit substrate. The exemplary embodiments of the present invention to be described below are provided by way of example so that the idea of the present invention can be sufficiently transferred to those skilled in the art to which the present invention pertains. Therefore, the present invention may be modified in many different forms and it should not be limited to the embodiments set forth herein. In the drawings, the size, and the thickness of the device may be exaggerated for convenience. Like reference numerals denote like elements throughout the specification.

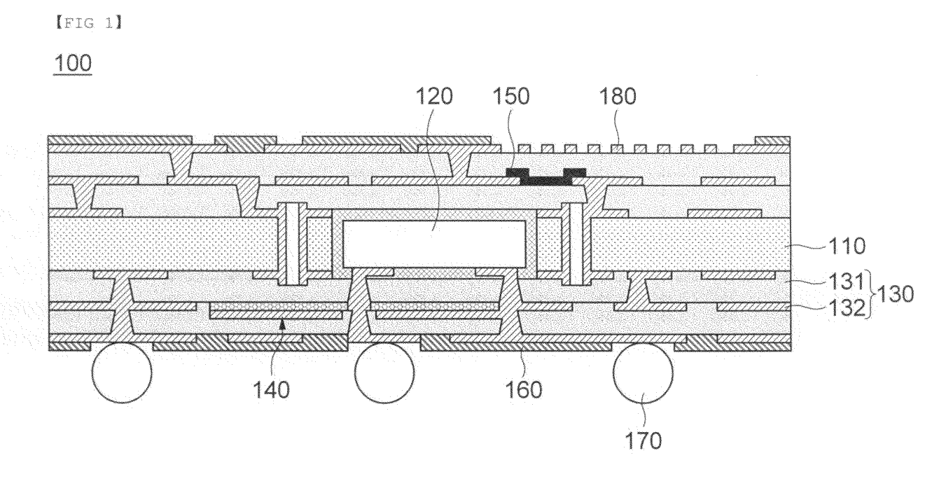

FIG. 1 is a cross-sectional view of a printed circuit substrate according to an exemplary embodiment of the present invention.

Referring to FIG. 1, a printed circuit substrate 100 may be an embedded substrate in which electronic components are embedded.

In detail, the printed circuit substrate 100 may include an insulator 110 including cavities, electronic components 120 disposed in the cavities, and a buildup layer 130 disposed on at least one of the top and bottom surfaces of the insulator 110 including the electronic components 120. The buildup layer 130 may include an insulating layer 131 disposed on at least one of the top and bottom surfaces of the insulator 110 and a circuit layer 132 that is disposed on the insulating layer 131 to form an interlayer connection thereto.

An example of the electronic component 120 may be an active device such as a semiconductor device, etc. In addition, the printed circuit substrate 100 may further embed at least one additional electronic component, for example, a capacitor 140, a resistive element 150, etc., rather than embedding only one electronic component 120. Therefore, the exemplary embodiment of the present invention does not limit the types or numbers of electronic components.

Herein, the insulator 110 and the insulating layer 131 may serve to insulate an inter-circuit layer and an inter-electronic component and also serve as a structural member to hold the rigidity of the package.

In this case, when the wiring density of the printed circuit substrate 100 is increased, the insulator 110 and the insulating layer 131 require low-K characteristics in order to reduce both the inter-circuit layer noise and the parasitic capacitance while also requiring low loss propertie characteristics in order to increase the insulating characteristics.

As such, at least any one of the insulator 110 and the insulating layer 131 may be formed from the insulating resin composition including a solvent capable of dissolving soluble fluorine-based resin, thermosetting resin, and both the soluble fluorine-based resin and the thermosetting resin in order to lower the dielectric constant, the dielectric loss, etc., while maintaining rigidity.

In detail, the fluorine-based resin is a material having low dielectric characteristic and low loss propertie characteristic, as compared to liquid crystal polymer (LCP) or benzocyclobutene (BCB). Therefore, the fluorine-based resin may serve to lower the dielectric characteristics and the dielectric loss characteristics of the insulator 110 or the insulating layer 131. In this case, the fluorine-based resin may be selected as a material having solubility to be applied to the process of manufacturing the printed circuit substrate 100. For example, the fluorine-based resin may be poly vinylidene fluoride or derivatives thereof.

The content of the fluorine-based resin may be in the range of 5 parts by weight to 40 parts by weight for the entire content of the insulating resin composition. Herein, when the content of the fluorine-based resin is below 5 parts by weight, it cannot meet the low dielectric characteristics and the low loss propertie characteristics, and when the fluorine-based resin exceeds 40 parts by weight, it cannot meet the mechanical properties to be applied to the printed circuit substrate and may also lower the adhesion with a metal layer on which the circuit layer is formed, for example, a copper layer.

The fluorine-based resin can simultaneously meet both the low dielectric characteristics and the low loss propertie characteristics as well as the mechanical properties such as wear-resistance, heat-resistance, low thermal expansion, etc., but does not have the mechanical properties enough to be applied to the printed circuit substrate alone.

Therefore, the thermosetting resin is included in the insulating resin composition in order to serve to supplement the characteristics of the fluorine-based resin, such as adhesive strength, thermal stability, and thermal expansion coefficient, etc., that are absent in the fluorine-based resin, which prevents the fluorine-based resin from being used alone for the printed circuit substrate.

An example of the thermosetting resin may include any one or two or more of epoxy-based resin, phenol-based resin, acryl-base resin, and imide-based resin. In this case, an example of the epoxy-based resin may include naphthalene-based epoxy resin, bisphenol A type epoxy resin, phenol novolac epoxy resin, cresol novolac epoxy resin, rubber-modified epoxy resin, phosphor-based epoxy resin, or the like.

The solvent may be made of a material capable of simultaneously dissolving fluorine-based resin and thermosetting resin. In this case, the solvent may be any one of an ester-based solvent and an amine-based solvent or a mixture of thereof. An example of the material usable as a solvent may include methyl ethyl ketone, dimethylacetamide, ethanol amine, isopropanol amine, and triethanol amine.

Therefore, the insulating resin composition includes fluorine-based resin and thermosetting resin mixed by the solvent blending, thereby making to possible to form the insulator 110 or the insulating layer 131 through a simple solution process, a coating method, or a printing method using the insulating resin composition.

In addition, the insulating resin composition further includes an inorganic filler, thereby making it possible to increase the strength of the insulator 110 or the insulating layer 131.

In this case, an example of the inorganic filler may be any one of graphite, carbon black, silica, and clay or a mixture of two or more thereof. However, the present invention is not limited thereto.

In addition, the uppermost layer and the lowest layer of the printed circuit substrate may further be provided with solder resists 160 that expose a pad 180 electrically connected to the circuit layer 132.

Further, the lowest layer of the printed circuit substrate may further be provided with external connection units 170 electrically connected to the exposed pad by the solder resist 160. An example of the external connection unit 170 may be a solder ball, a solder bump, or the like.

Therefore, as in the exemplary embodiment of the present invention, the low dielectric characteristics and the low loss propertie characteristics can be met by forming the insulating resin composition including the fluorine-based resin.

In addition, the fluorine-based resin has soluble characteristics for the same solvent as the thermosetting resin, such that it can be sufficiently applied to the process of manufacturing the printed circuit substrate.

The exemplary embodiment of the present invention describes that the insulating resin composition is applied to the embedded substrate, but is not limited thereto. The insulating resin composition may be used to form the insulating material of the general printed circuit substrate or the package substrate.

Hereinafter, the present invention will be described in more detail with reference to the following Examples, but the scope of the present invention is not limited thereto.

### EXAMPLES

A silica slurry was prepared by dispersing silica having a size range of an average particle of 0.2 to 1 μm in 2-methoxy ethanol.

Thereafter, a mixture was prepared by adding 400 g of naphthalene epoxy resin having an average equivalent of epoxy of 100 to 300, 400 g of bisphenol A type epoxy resin having an average equivalent of epoxy of 100 to 1,200 and 200 g of poly vinylidene fluoride to 2,300 g of the prepared silica slurry, 337 g of methyl ethyl ketone (MEK) thereto, and then agitating and dissolving them at 300 rpm at a normal temperature.

Thereafter, 380 g of amino triazine-based hardener was applied to the mixture and then, further agitated at 300 rpm for 1 hour.

Thereafter, 2.5 g of 2-ethyl-4-methyl imidazole and silica based leveling agent was added at 1.5 party per hundred parts (PHR) of resin of the entire mixture and agitated for 1 hour, thereby preparing the insulating resin composition.

Thereafter, the insulating resin composition was applied and completely hardened on the PET film and then, Dk values and Df values were measured at 1 GHz.

### Comparative Example

The insulating resin composition was prepared with the same method and composition as the foregoing exemplary embodiment, other than mixing 500 g of naphthalene epoxy resin having an average equivalent of epoxy of 100 to 300 with 500 g of bisphenol A type epoxy resin having an average equivalent of epoxy of 100 to 1,200 without adding poly vinylidene fluoride.

Thereafter, the insulating resin composition was applied and completely hardened on the PET film and then, Dk values and Df values were measured at 1 GHz.

The following Table 1 compares Dk values with Df values according to Experiment Example and Comparative Example.

TABLE 1

| | Experiment | Comparative |
|---|---|---|
| | Example | Example |
| Dk Value | 2.5 | 3.2 |
| Df Value | 0.005 | 0.02 |

As in Table 1, when the insulating resin composition includes the added poly vinylidene fluoride, it could be confirmed that the dielectric constant (Dk value) and the dielectric loss value (Df value) are low.

Therefore, as in the exemplary embodiment of the present invention, the poly vinylidene fluoride dissolved in the same solvent as the epoxy-based resin is included in the insulating resin composition, thereby making it possible to manufacture the insulating layer capable of having low dielectric constant and dielectric loss value through the simple process.

The insulating resin composition of the present invention can manufacture the substrate having characteristics, such as low loss propertie, low dielectric constant, etc., with the simple process, including the soluble fluorine-based resin.

Further, the insulating resin composition of the present invention can meet the mechanical properties of the substrate, including the thermosetting resin.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. An insulating resin composition, comprising:
soluble fluorine-based resin;
thermosetting resin; and
a solvent capable of simultaneously dissolving the soluble fluorine-based resin and the thermosetting resin.

2. The insulating resin composition according to claim 1, wherein the fluorine-based resin includes poly vinylidene fluoride or derivatives thereof.

3. The insulating resin composition according to claim 1, wherein the content of the fluorine-based resin is in the range of 5 parts by weight to 40 parts by weight for the entire content of the insulating resin composition.

4. The insulating resin composition according to claim 1, wherein the solvent is made of any one of an ester-based solvent and an amine-based solvent or a mixture thereof.

5. The insulating resin composition according to claim 4, wherein the solvent includes methyl ethyl ketone, dimethylacetamide, ethanolamine, isopropanolamine, and triethanolamine or a mixture of two or more thereof.

6. The insulating resin composition according to claim 1, wherein the thermosetting resin includes any one or two or more of epoxy-based resin, phenol-based resin, acryl-based resin, and imide-based resin.

7. The insulating resin composition according to claim 1, wherein the insulating composition further includes an inorganic filler.

8. A printed circuit substrate using an insulating resin composition, comprising:
an insulator including cavities;
electronic components disposed in the cavities; and
a buildup layer that includes an insulating layer disposed on at least any one of the top and bottom surfaces of the insulator including a semiconductor device and a circuit layer disposed on the top surface of the insulating layer to form an interlayer connection thereto,
wherein at least any one of the insulator and the insulating layer includes a solvent capable of dissolving soluble fluorine-based resin, thermosetting resin, and both the soluble fluorine-based resin and the thermosetting resin.

9. The printed circuit substrate according to claim 8, wherein the fluorine-based resin includes poly vinylidene fluoride or derivatives thereof.

10. The printed circuit substrate according to claim 8, wherein the content of the fluorine-based resin is in the range of 5 parts by weight to 40 parts by weight for the entire content of the insulating resin composition.

11. The printed circuit substrate according to claim 8, wherein the solvent is made of any one of an ester-based solvent and an amine-based solvent or a mixture thereof.

12. The printed circuit substrate according to claim 11, wherein the solvent includes methyl ethyl ketone, dimethylacetamide, ethanolamine, isopropanolamine, and triethanolamine or a mixture of two or more thereof.

13. The printed circuit substrate according to claim 8, wherein the thermosetting resin includes any one or two or more of epoxy-based resin, phenol-based resin, acryl-based resin, and imide-based resin.

14. The printed circuit substrate according to claim 8, wherein the insulating composition further includes an inorganic filler.
